(19) United States
(12) Patent Application Publication
(10) Pub. No.: US 2008/0032451 A1
(43) Pub. Date: Feb. 7, 2008

(54) METHOD OF PROVIDING INVERTED PYRAMID MULTI-DIE PACKAGE REDUCING WIRE SWEEP AND WEAKENING TORQUES

(75) Inventors: Avraham MEIR, Rishon Lezion (IL); Doron TEOMIM, Modiin (IL); Alex SHEVACHMAN, Beer Sheva (IL); Reuven LEVITANUS, Beer Sheva (IL); Valery ISRAILIT, Maale Adumim (IL)

Correspondence Address: MARK M. FRIEDMAN, C/O DISCOVEY DISPATCH , 9003 FLIRIN WAY, UPPER MARLBORO, MD, 20772, US

(73) Assignee: SanDisk IL Ltd., Kfar Saba (IL)

(21) Appl. No.: 11/767,535

(22) Filed: Jun. 25, 2007

Related U.S. Application Data
(60) Provisional application No. 60/821,582, filed on Aug. 7, 2006.

(51) Int. Cl. H01L 21/00

(52) U.S. Cl. 438/109; 257/E23.003

(57) ABSTRACT

An inverted pyramid multi-die package provides, for each die pad on an upper die, a rigid support underneath extending to a substrate. Such configuration reduces both the wire sweep and weakening torques. A lower die, smaller than the upper die in at least one dimension, may be positioned between the upper die and the substrate. The two dice may or may not contact each other, or they may contact each other via an intermediate spacer. The lower die may be a flip chip. The multi-die package may be fashioned without the lower die or the substrate. Wire sweep is reduced, because the second die is smaller than the upper die in at least one dimension. Weakening torques are reduced, because spacers at the periphery of the upper die absorb the impact of bonding wires thereon.

### RELATED APPLICATION

This application claims priority under 35 U.S.C. §119(e) to U.S. Provisional Application No. 60/821,582, filed Aug. 7, 2006, which is hereby incorporated by reference in its entirety.

This application is related to U.S. patent application Ser. No. ______ of the same inventors, which is entitled “INVERTED PYRAMID MULTI-DIE PACKAGE REDUCING WIRE SWEEP AND WEAKENING TORQUES” and filed on the same day as the present application. This application, also claiming priority to U.S. Provisional Application No. 60/821,582, is incorporated in its entirety as if fully set forth herein.

### BACKGROUND

A trend in the electronics industry is to offer products that are smaller, have more functionality, perform better, and cost less. Electronic products typically include multiple electronic dice of integrated circuits, and stacking the dice vertically in molded packages is often considered for space savings. Such die stacking effectively increases functionality on a given surface area of the substrate on which the dice are mounted. A package with more than one die is known as a “multi-die package.”

One way of stacking dice, known as “pyramid” stacking, is to mount a smaller die on a larger die. FIG. 1 illustrates an example multi-die package 10, in which a smaller die 12 is mounted on a larger die 14. Larger die 14 is mounted on a substrate 16. Die pads 18 on smaller die 12, die pads 20 on larger die 14, and die pads 22 on substrate 16 are electrically connected to circuitry on smaller die 12, larger die 14, and substrate 16, respectively. (For clarity, only one of the illustrated die pads for each die or substrate is labeled.) External wires contact the die pads to provide electrical connection to the internal circuitry on the dice 12, 14 and substrate 16. Wire 24 electrically connects circuitry of smaller die 12 to circuitry of larger dice 14, wire 26 electrically connects circuitry of smaller die 12 to circuitry of substrate 16, and wire 28 electrically connects circuitry of larger die 14 to substrate 16. (For clarity, only three wires are illustrated, but typical assemblies include many more such wires.) Wire 24 between substrate 16 and smaller die 12 is the longest due to the greater vertical and horizontal distances it must extend relative to the other wires. After the dice are mounted on the substrate and the circuitry thereof is interconnected, the package is encapsulated, for example, by a resin (not shown).

The encapsulation process involves a injecting a material to surround the package and to later solidify. The flowing encapsulation liquid tends to displace the longer wires, sometimes to the extent of short circuiting with other wires. Even if the displacement is not enough to cause short circuiting, the displacement of wires can affect the inductance of adjacent wires, and the greater length of the wires increases their resistances. This general displacement of wires is known as “wire sweep.” The wire sweep problem increases as wire lengths increase.

An alternate design, known as an “inverted pyramid” design, does not require wires to be as long from the substrate to the farther die. FIG. 2 illustrates an example of the “inverted pyramid” design.

In multi-die package 30 of FIG. 2, a smaller die 32 is mounted on a substrate 34, a spacer 36 is mounted on smaller die 32, and a larger die 38 is mounted on spacer 36. Spacer 36, which is an element without contact pads, contacts only a portion the surface of smaller die 32 that is facing larger die 38 and thus permits surface area to be available on the smaller die for contact pads for wires, such as for a contact pad 40 for a wire 42 from smaller die 32 to substrate 34.

As a variant of multi-package 30 in FIG. 2, smaller die 32 may be replaced with a flip chip, that is, a chip in which contacts functioning as die pads are on the chip's surface that contacts the substrate. The substrate has corresponding contacts to effect electrical connections between the substrate and the flip chip. Thus, the multi-die package does not need a spacer to separate the flip chip from the larger die.

This inverted pyramid design, either that of FIG. 2 or that of the variant described above, does not require wires as long as those of the pyramid design of FIG. 1 to extend from the substrate to the farther die. A wire 44 extending from a contact pad 46 on substrate 34 to a contact pad 48 on larger die 38 does not extend as far horizontally as the analogous wire in FIG. 1. Thus, the present inventors recognized the inverted pyramid design as an option to be considered for addressing the problem of wire sweep.

The inventor also realized though that a drawback of the inverted pyramid design is that the contact pads at the periphery of the larger die, such as contact pad 48, are positioned on the die at a position that has no direct support between the die and the substrate. Thus, the impact that occurs from bonding wire 44 to contact pad 48 causes a weakening torque about spacer 36 or about the smaller die, if the smaller die is implemented as a flip chip without a spacer.

Multi-die package 50 in FIG. 3 resembles multi-die package 32 of FIG. 2, but a spacer 52 is positioned between a substrate 54 and a larger die 56. A wire 58 extends from a contact pad 60 on substrate 54 to a contact pad 62 on larger die 56. Because contact pad 62 is positioned on larger die 56 at a position that has direct support between it and substrate 54, the present inventors observe that there is no weakening torque from the impact of bonding wire 58 to contact pad 62.

Multi-die package 50 of FIG. 3 also differs from multi-die package 32 of FIG. 2 in the respect that there is no spacer between larger die 56 and a smaller die 64 contacting the middle of larger die 56. Instead, a spacer 66 is positioned at the periphery of larger die 56. Spacer 66 contacts smaller die 64 in its middle region to enable contact pads to be positioned along its periphery. Thus, a wire 68 connecting larger die 56 at a contact pad 70 above spacer 66 must extend a farther horizontal distance to substrate 54. Accordingly, wires such as wire 68 are more susceptible to wire sweep problems.

Another feature of multi-die package 50 of FIG. 3, which is not apparent from the cross-sectional view, is that some of the contact pads on larger die 56 are not directly supported over substrate 54. That is, for some of the contact pads on the periphery of larger die 56, there is no rigid element, such as a spacer or portion of a lower die, that extends between larger die 56 and substrate 54 to brace larger die 56 against force directed thereon. Thus, the impact from bonding wires to those contact pads causes a weakening torque on larger die 56.

In the prior art discussed above, the multi-die packages suffer from the problems of wire sweep and/or weakening torques. The wire sweep problem occurs when the wires must extend excessive horizontal distances over one die to reach another die mounted thereon. The weakening torques occur when upper die support is not provided. The present inventors are unaware of any multi-die packages designed to address these problems by providing, for each die pad on an upper die, a rigid support underneath the upper die extending to the substrate thereunder.

### SUMMARY

Described herein is an inverted pyramid multi-die package, which provides, for each die pad on an upper die, a rigid support underneath the upper die extending to the substrate thereunder. Such an arrangement reduces both the problems of wire sweep and of weakening torques.

The present invention may be embodied as a multi-die package that has a substrate, one or more spacers attached to the substrate, and a first die attached to the spacers. The first die in this embodiment has one or more first die pads connected to leads, and, for each of the first die pads, one of the spacers is positioned between the die pad and the substrate. A second die may be attached to the substrate with at least a portion of the second die positioned between the substrate and the first die. The multi-die package may or may not be configured such that the two dies physically contact each other. The second die may be a flip chip. An additional spacer may be positioned to contact both dies.

In another embodiment of the invention, a multi-die package has a first die, one or more spacers attached to one side of the first die; and a second die having one side facing the one side of the first die. The first die is larger than the second die in at least one dimension parallel to the one side of the first die. No rigid element or set of elements contacting the one side of the first die can transfer force from that side to the one side of the second die. A substrate may be attached to the second die and to one or more of the spacers. The second die may be a flip chip.

In still another embodiment of the invention, a multi-die package has a first die, one or more spacers attached to a side of the first die, a substrate attached to the spacers, and a second die. The spacers have a height perpendicular to the one side of the first die. The substrate is attached to each spacer that is attached to the one side of the first die. The second die is attached to the substrate and has a side facing the one side of the first die. The first die is larger than the second die in at least one dimension parallel to the one side of the first die; and the second die has a height perpendicular to the one side of the first die. The height of the second die is less than that of the spacers. The may second die may be a flip chip.

In yet another embodiment of the invention, a multi-die package has a first die having a periphery, one or more spacers attached to one side of the first die, and a second die having a side facing the one side of the first die. The first die is larger than the second die in at least one dimension parallel to the one side of the first die. No rigid element contacting the one side of the first die at the periphery can transfer force from the one side of the first die to the one side of the second die. The multi-die package may include a substrate attached to the second die and to the spacers, and the second die may be a flip chip.

The invention may also be embodied as a method of providing a multi-die package. This method includes mounting one or more spacers on a substrate, mounting a first die on the spacers, and positioning first die pads on the die such that, for each of the die pads, one of the spacers is positioned between the first die pad and the substrate. The method may further include mounting a second die to the substrate such that at least a portion of the second die is positioned between the substrate and the first die. The second die may be mounted so that the entire second die is between the substrate and the first die. The first and second dice may be arranged so that the first die has a first side facing the second die and the second die has a second side facing the first die, so that no rigid element contacting the first side can transfer force from the first side to the second side.

The method of providing a multi-die package may alternatively include attaching one or more spacers to one side of a first die, and positioning a second die to have a side facing the one side of the first die. The second die in this embodiment is smaller than the first die in at least one dimension parallel to the one side of the first die. The multi-die package is provided in such a fashion that no rigid element that contacts the one side of the first die can transfer force to the one side of the second die.

Another alternative to the method of providing a multi-die package includes attaching one or more spacers to one side of a first die, attaching a substrate to each of those spacers, and attaching a second die to the substrate. The spacers and the second die used have heights perpendicular to the one side of the first die, and the height of the second die is less than the height of the spacers. The second die has one side facing the one side of said first die, and the second die is smaller than the first die in at least one dimension parallel to the one side of the first die.

Yet another embodiment of the method of providing a multi-die package includes attaching one or more spacers to one side of a first die and positioning a second die such that one side of the second die faces the one side of the first die. The second die is smaller than the first die in at least one dimension parallel to the one side of the first die. The first die has a periphery, and no rigid element contacting the one side of the first die at the periphery can transfer force from the one side of the first die to the one side of the second die.

Embodiments of the present invention are described in detail below with reference to the accompanying drawings, which are briefly described as follows:

### BRIEF DESCRIPTION OF THE DRAWINGS

The invention is described below in the appended claims, which are read in view of the accompanying description including the following drawings, wherein:

FIG. 1 illustrates a prior art multi-die package in a pyramid configuration;

FIG. 2 illustrates a prior art multi-die package in an inverted pyramid configuration;

FIG. 3 illustrated a prior art multi-die package resembling that of FIG. 2, but one die is shifted horizontally, and a spacer is positioned between the two dice;

FIG. 4 illustrates a cross-sectional view of one embodiment of the inventive multi-die package;

FIG. 5 is a plan view of the multi-die package of FIG. 4;

FIG. 6 is a cut-away plan view of the multi-die package of FIG. 4 along the 6-6 line of FIG. 4 FIG. 7 illustrates a cross-sectional view of a first alternate embodiment of the inventive multi-die package; and

FIG. 8 illustrates a cross-sectional view of a second alternate embodiment of the inventive multi-die package.

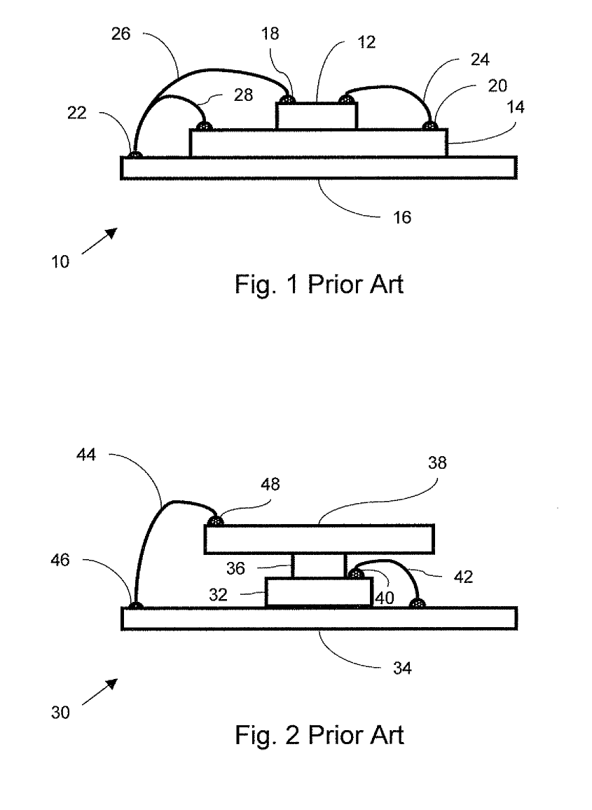

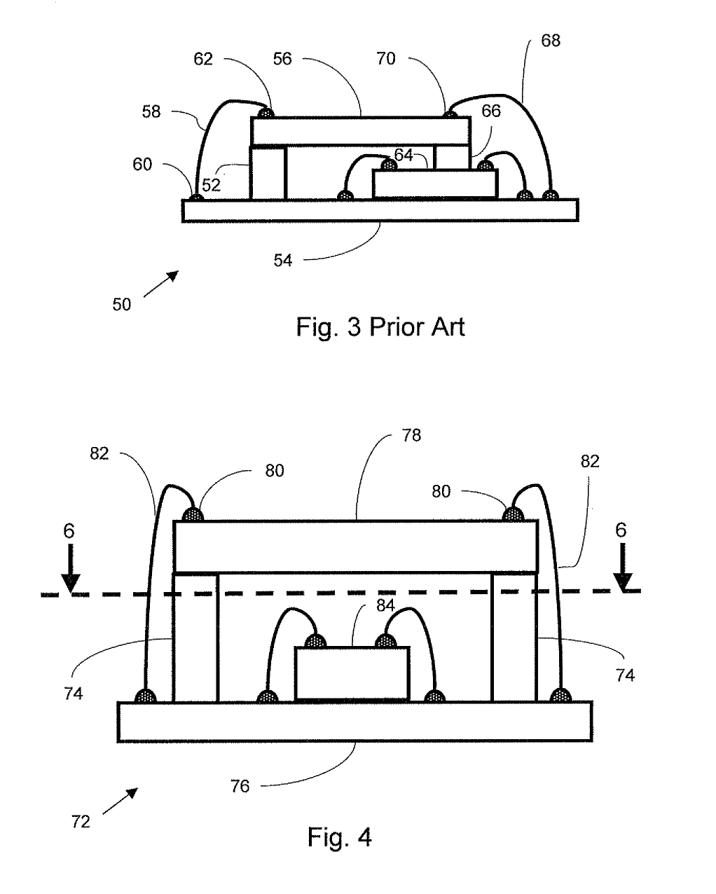

### DETAILED DESCRIPTION

The invention summarized above and defined by the claims below will be better understood by referring to the present detailed description of embodiments of the invention. This description is not intended to limit the scope of claims but instead to provide examples of the invention. Described first is one embodiment of a multi-die package in accordance with the invention. Described next are variants of the first embodiment that are within the scope of the invention. Also described is a method of providing a multi-die package.

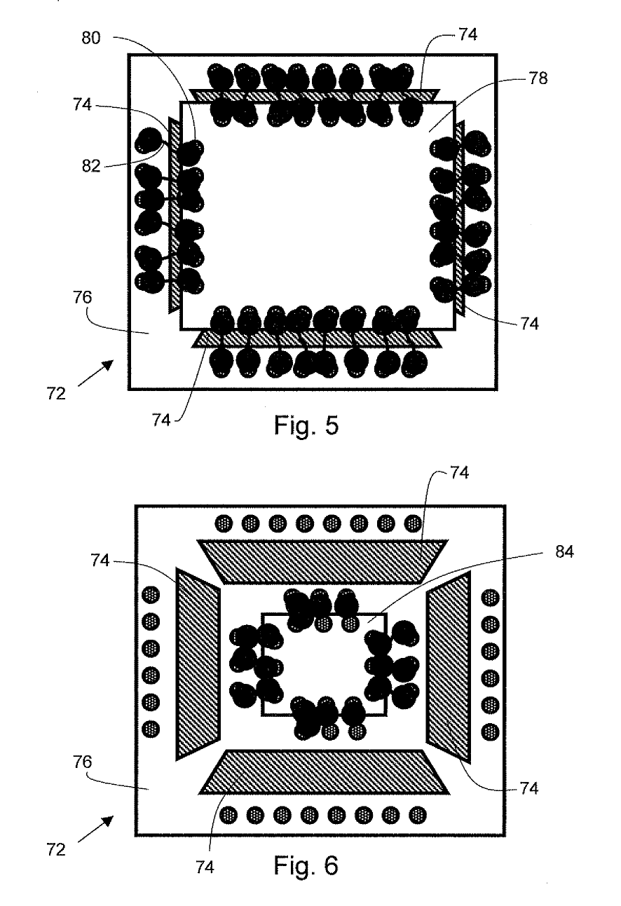

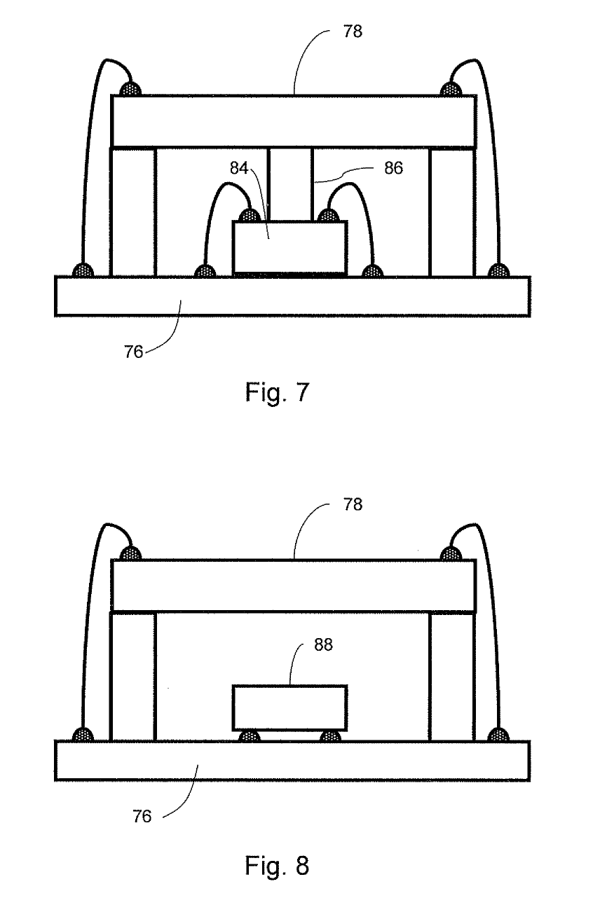

One embodiment of the present invention is multi-die package 72 illustrated in FIGS. 4-6. FIG. 4 is a cross-sectional view, FIG. 5 is a plan view, and FIG. 6 is a cut-away plan view along the 66 line of FIG. 4. In multi-die package 72, spacers 74 are attached to a substrate 76, and a first die 78 is attached to spacers 74. First die 78 has first die pads 80 (not all labeled in each figure for clarity) connected to leads 82, and, for each of first die pads 80, one of spacers 74 is positioned between the die pad and substrate 76. A second die 84 is attached to substrate 76 with second die positioned 84 between substrate 76 and first die 78.

As is apparent from FIGS. 4-6, first die 78 is larger than second die 84 in two dimensions, length and width, and the height of second die 84 is less than the height of spacers 74. In this embodiment, multi-die package 72 is configured such that dies 78, 84 do not physically contact each other. That is, no rigid element or set of elements (for example, one element on top of another) contacting first die 78 can transfer force from first die 78 to second die 84. Thus, elements, such as spacers 74 contacting first die 78 at its periphery cannot transfer force (for example, the impact from bonding wires) to second die 84.

After the dice are mounted on the substrate and the circuitry thereof is interconnected, the package may be encapsulated, for example, by a material such as resin. The material can be injected to surround the package, to pass through gaps between adjacent spacers 74, and then to solidify. As is apparent from the drawings, the arrangement of multi-die package 72 reduces both the problem of wire sweep and of weakening torques, because the wires extending from substrate 76 to first die 78 do not need to extend excessive horizontal distances, and, for each die pad on first die 78, a spacer 74 is positioned between first die 78 and substrate 76.

Multiple variants of the embodiment of FIGS. 4-6 are within the scope of the invention. For example, an additional spacer 86 may be positioned between first die 78 and second die 84, as shown in FIG. 7. Alternatively, second die 84 may be replaced with a flip chip 88, as shown in FIG. 8. Further, the multi-die package may be fashioned without second die 84/flip chip 88, without substrate 76, or without both.

Multi-die package 72 of FIGS. 4-6 may be provided by mounting spacers 74 on substrate 76, mounting first die 78 on spacers 74, and positioning first die pads 80 on first die 78 such that, for each die pad 80, one of spacers 74 is positioned between the first die pad and substrate 76. Second die 84 is mounted to substrate 76 such that second die 84 is positioned between substrate 76 and first die 78. First and second dice 78, 84 are arranged so that no rigid element or set of elements contacting the dice can transfer force from one to the other.

Having thus described exemplary embodiments of the invention, it will be apparent that various alterations, modifications, and improvements will readily occur to those skilled in the art. Alternations, modifications, and improvements of the disclosed invention, though not expressly described above, are nonetheless intended and implied to be within spirit and scope of the invention. Accordingly, the foregoing discussion is intended to be illustrative only; the invention is limited and defined only by the following claims and equivalents thereto.

We claim:

1. A method of providing a multi-die package, the method comprising:
mounting one or more spacers on a substrate;
mounting a first die on said one or more spacers;
positioning first die pads on said die such that, for each of said first die pads, one of said spacers is positioned between said first die pad and said substrate.

2. The method of claim 1 further comprising:
mounting a second die to said substrate such that at least a portion of said second die is positioned between said substrate and said first die.

3. The method of claim 2, wherein said second die is mounted so that the entire second die is between said substrate and said first die.

4. The method of claim 2, wherein said first die has a first side facing said second die, said second die has a second side facing said first die; and no rigid element or set of elements contacting said first side can transfer force from said first side to said second side.

5. A method of providing a multi-die package, the method comprising:
attaching one or more spacers to one side of a first die; and
positioning a second die to have a side facing said one side of said first die, said second die being smaller than said first die in at least one dimension parallel to said one side of said first die,
wherein no rigid element or set of elements contacting said one side of said first die can transfer force from said one side of said first die to said one side of said second die.

6. A method of providing a multi-die package, the method comprising:
attaching one or more spacers to one side of a first die, said one or more spacers having a height perpendicular to said one side of said first die;
attaching a substrate to said one or more spacers, wherein said substrate is attached to each spacer that is attached to said one side of said first die; and
attaching a second die to said substrate, said second die having one side facing said one side of said first die, said second die being smaller than said first die in at least one dimension parallel to said one side of said first die;
wherein said second die has a height perpendicular to said one side of said first die, said height of said second die being less than said height of said one or more spacers.

7. A method of providing a multi-die package, the method comprising:
attaching one or more spacers to one side of a first die, said first die having a periphery; and
positioning a second die such that one side of said second die faces said one side of said first die, said second die being smaller than said first die in at least one dimension parallel to said one side of said first die,
wherein no rigid element or set of elements contacting said one side of said first die at said periphery can transfer force from said one side of said first die to said one side of said second die.
